(19) United States
(12) Patent Application Publication
(10) Pub. No.: US 2005/0079705 A1
(43) Pub. Date: Apr. 14, 2005

(54) Process for producing semiconductor device and semiconductor device

(76) Inventor: Koichi Takeuchi, Kanagawa (JP)

Correspondence Address: RADER FISHMAN & GRAUER PLLC, LION BUILDING, 1233 20TH STREET N.W., SUITE 501, WASHINGTON, DC, 20036, US

(21) Appl. No.: 10/506,792

(22) PCT Filed: Mar. 20, 2003
(86) PCT No.: PCT/JP03/03454

(30) Foreign Application Priority Data
Mar. 22, 2002 (JP) 2002-80056

(51) Int. Cl. H01L 21/4763

(52) U.S. Cl. 438/637; 438/623; 438/963

(57) ABSTRACT

A method of producing a semiconductor device wherein an already formed opening portion inner wall of an organic based interlayer insulation film is prevented from changing in quality or corroding when performing etching on other organic material. The production method includes a step of depositing organic based interlayer insulation films (4, 6), a step of forming an opening on the organic based interlayer insulation films (4, 6), and a step of silylating a wall surface portion of the organic based interlayer insulation films (4, 6) exposed in the opening portion for reforming (forming reformed layers (4a, 6a) by silylation). A more preferable production method further includes a step of forming protective layers (4b, 6b) including an inorganic based insulation material on a surface of the silylated opening portion wall surface.

### TECHNICAL FIELD

The present invention relates to a method of producing a semiconductor device including a step of forming an opening portion on an organic based interlayer insulation film wherein relative permittivity can be made lower than that in the case of an inorganic insulation material, and a semiconductor device having a wiring structure of so-called dual damascene structure.

### BACKGOUND ART

Due to demands for a semiconductor circuit at a higher speed with lower power consumption, copper has been used as a wiring material. Since it is difficult to perform etching on copper, the dual damascene method of forming wiring trenches and via holes on an interlayer insulation film, then burying copper therein at a time has been widely applied. The dual damascene method is roughly divided to a first-via type for engraving a via plug first and a first-trench type for engraving a wiring trench first.

Below, a method of forming a first-via type dual damascene structure will be explained.

FIG. 1 to FIG. 8 are sectional views showing a method of forming a conventional first-via type dual damascene structure. Note that in these drawings, the case of further forming a via hole and a wiring layer together on a wiring layer, but the basic process is the same also in the case of forming a via hole and a wiring layer on a semiconductor substrate.

As shown in FIG. 1, on a first interlayer insulation film 101 already formed with a wiring layer 102, an etching stopper film 103, a second interlayer insulation film 104, an etching stopper film 105, a third interlayer insulation film 106 and a hard mask film 107 are stacked in order.

As shown in FIG. 2, by using a lithography technique and a dry etching technique, the hard mask film 107, the third interlayer insulation film 106, the etching stopper film 105, and the second interlayer insulation film 104 are partially etched until the etching stopper film 103 as the lowermost layer is exposed, so that a via hole VH is formed.

As shown in FIG. 3, an etching stopper resin 108 is coated to the entire surface and buried in the via hole VH. At this time, sidewalls of the via hole VH is completely covered with the resin 108.

As shown in FIG. 4, a resist R is coated and a trench shaped wiring pattern RP is transferred thereon by using a lithography technique.

As shown in FIG. 5, by using the resist R as a mask, the resin 108 thinly coated to the upper surface and sidewalls of the via hole VH, the hard mask film 107 and the third interlayer insulation film 106 are subjected to dry etching, so that a wiring pattern trench CG is engraved.

At this time, a resin 108b remains on the bottom of the via hole VH and functions as a stopper when performing etching on the hard mask 107 and the third interlayer insulation film 106 so as to prevent a lower wiring layer (or a substrate) of the via hole VH from being damaged as a result that the etching stopper layer 103 is dug. The etching stopper film 103 is normally thin. Therefore, the etching stopper film 103 is insufficient as a stopper when performing etching on the hard mask film 107 and the third interlayer insulation film 106 and an etching stopper composed of the resin 108b is necessary.

Next, as shown in FIG. 6, the resist R and resins 108a and 108b are removed by oxygen ashing.

As shown in FIG. 7, overall dry etching is performed to remove exposed portions of the etching stopper films 103 and 105. At this time, a part of an upper surface of the hard mask film 107 is shaved and a thinner hard mask film 107′ remains.

On inner walls of the via hole VH and the wiring trench CG, a barrier metal layer 109 and a copper plating seed layer are thinly formed and copper 110 is buried by a plating method. After that, excessive copper on the upper surface is removed by using the CMP (Chemical Mechanical Polishing) method. At this time, the hard mask film 107′ functions as a polishing stopper in the CMP step of the copper. The hard mask film 107′ is finally removed in a CMP step under a different condition from that in the case of copper.

From the above, as shown in FIG. 8, a dual damascene structure of copper wiring composed of the barrier metal layer 109 and copper 110 is completed.

For a purpose of reducing a wiring delay, an organic based low relative permittivity film has been proposed for an interlayer insulation film.

However, when an organic based film is used for the second and third interlayer insulation films 104 and 106, since the buried resin 108 and the resist R are also organic based films, a via hole inner wall portion of the organic based second and third interlayer insulation films 104 and 106 changes in quality or corrodes in the steps of peeling the buried resin 108 and the resist R in FIG. 5 and FIG. 6. Therefore, in the step in FIG. 8, the barrier metal layer 109 cannot be preferably formed on the via hole inner wall portion. As a result, the copper 110 diffuses into the second and third interlayer insulation films 104 and 106 when burying the copper 110, or a void arises in the copper 110 buried in the via hole VH, which results in a decline of electric characteristics of a device.

Also, when a corrosion amount of the interlayer insulation films 104 and 106 is large, a variety of problems arise, such that a line width error arises in the lithography step, a distance cannot be secured between the wiring and other wiring, and an alignment error thereof arises.

### DISCLOSURE OF THE INVENTION

An object of the present invention is to provide a method of producing a semiconductor device, including a step capable of protecting an already formed opening portion of an organic based interlayer insulation film, and a semiconductor device.

A method of producing a semiconductor device according to a first aspect of the present invention is to attain the above object and includes a step of depositing organic based interlayer insulation films; a step of forming an opening portion on the organic based interlayer insulation films; and a step of silylating to reform a wall surface portion of the organic based interlayer insulation films exposed in the opening portion.

Preferably, a step of forming protective layers including an inorganic based insulation material on a silylated surface of the opening portion wall surface is furthermore included.

Also preferably, a step of forming an organic based substance in a state of being formed with the opening portion and removing the organic based substance at least from the opening portion after the silylation is furthermore included.

Furthermore preferably, a porous organic insulation film is formed as the organic based interlayer insulation films.

A method of producing a semiconductor device according to a second aspect of the present invention is to attain the above objects, and is a method of producing a semiconductor device including a step of forming an opening portion on organic based interlayer insulation films, including a step of depositing organic based interlayer insulation films containing a silylating agent; a step of forming an opening portion on the organic based interlayer insulation films; and a step of forming protective layers composed of an inorganic based interlayer insulation material on an inner wall surface of the opening portion containing a silylating agent.

According to the method of producing a semiconductor device according to the first and second aspects, even in the case where after forming an opening portion on an organic based interlayer insulation film, other organic based material enters in the opening portion and there is a step of removing the same, etching of an organic based interlayer insulation material does not proceed on the opening portion inner wall portion changed in quality by silylation of the organic based material. For example, when removing a not silylated resist in a subsequent photoresist process, the opening portion is protected by the silylated portion and a shape thereof does not deform.

When using a porous organic based insulation film as an organic based interlayer insulation film, a silylating agent easily diffuses. Also, when a silylating agent is contained in an interlayer insulation film from the start, the silylation step becomes unnecessary.

According to a method of producing the present invention, only by adding a simple step of silylation, an opening portion once formed on an organic based interlayer insulation film can be protected in a step of removing other organic based material as explained above. Therefore, pattern accuracy can be maintained high when processing an organic based interlayer insulation film having lower relative permittivity than that of an inorganic based insulation material. Also, when burying a conductive material in the opening portion, the conductive material can be preferably buried. As a result, introduction of an organic based interlayer insulation film becomes easy, and a semiconductor device at a higher speed with lower power consumption comparing with a semiconductor device having an inorganic based interlayer insulation film can be easily realized.

A semiconductor device according to a third aspect of the present invention is to attain the above object, and comprises two organic based interlayer insulation films stacked on top of another, wherein a via hole is formed on a lower layer interlayer insulation film and a wiring trench connected to the via hole is formed on an upper layer interlayer insulation film of the two organic based interlayer insulation films, and having a wiring configuration that a conductive material is buried in the wiring trench and the via hole; wherein an inner wall portion of the via hole of a lower layer interlayer insulation film of the two interlayer insulation films is provided with a silylated molecule containing layer and a protective layer composes an inorganic based insulation substance formed on a via hole inner wall surface portion of the silylated molecule containing layer.

In this semiconductor device, since a silylated molecule containing layer and a protective layer are formed on a via hole inner wall portion of the lower layer interlayer insulation film, the shape is not deformed. As a result, a conductive material is preferably buried and a void, etc. do not arise. Also, when there are a plurality of such wiring structure, between wirings or a mutual distance between wiring and a via hole portion is maintained to be constant.

### BRIEF DESCRIPTION OF DRAWINGS

FIG. 1 is a sectional view after forming a hard mask film in forming a conventional first-via type dual damascene structure.

FIG. 2 is a sectional view after forming a via hole in forming a conventional first-via type dual damascene structure.

FIG. 3 is a sectional view after burying an organic based substance in forming a conventional first-via type dual damascene structure.

FIG. 4 is a sectional view after forming a resist having a wiring trench pattern in forming a conventional first-via type dual damascene structure.

FIG. 5 is a sectional view after forming a wiring trench in forming a conventional first-via type dual damascene structure.

FIG. 6 is a sectional view after removing a resist and resin in forming a conventional first-via type dual damascene structure.

FIG. 7 is a sectional view after removing a part of an etching stopper film in forming a conventional first-via type dual damascene structure.

FIG. 8 is a sectional view after performing the CMP of copper in forming a conventional first-via type dual damascene structure.

FIG. 9 is a sectional view of a wiring structure of a semiconductor device according to an embodiment of the present invention.

FIG. 10 is a sectional view after forming a hard mask film in producing a semiconductor device according to a first embodiment of the present invention.

FIG. 11 is a sectional view after forming a via hole in producing a semiconductor device according to a first embodiment of the present invention.

FIG. 12 is a sectional view after silylation in producing a semiconductor device according to a first embodiment of the present invention.

FIG. 13 is a sectional view after forming a protective layer in producing a semiconductor device according to a first embodiment of the present invention.

FIG. 14 is a sectional view after forming a resist having a wiring trench pattern in producing a semiconductor device according to a first embodiment of the present invention.

FIG. 15 is a sectional view after removing a part of an organic based anti-reflection film in producing a semiconductor device according to a first embodiment of the present invention.

FIG. 16 is a sectional view after removing a part of a hard mask film in producing a semiconductor device according to a first embodiment of the present invention.

FIG. 17 is a sectional view after forming a wiring trench in producing a semiconductor device according to a first embodiment of the present invention.

FIG. 18 is a sectional view after removing an etching stopper film in producing a semiconductor device according to a first embodiment of the present invention.

FIG. 19 is a sectional view after forming a protective layer in producing a semiconductor device according to a second embodiment of the present invention.

FIG. 20 is a sectional view after forming a wiring trench in producing a semiconductor device according to a second embodiment of the present invention.

FIG. 21 is a sectional view after performing the CMP of copper in producing a semiconductor device according to a second embodiment of the present invention.

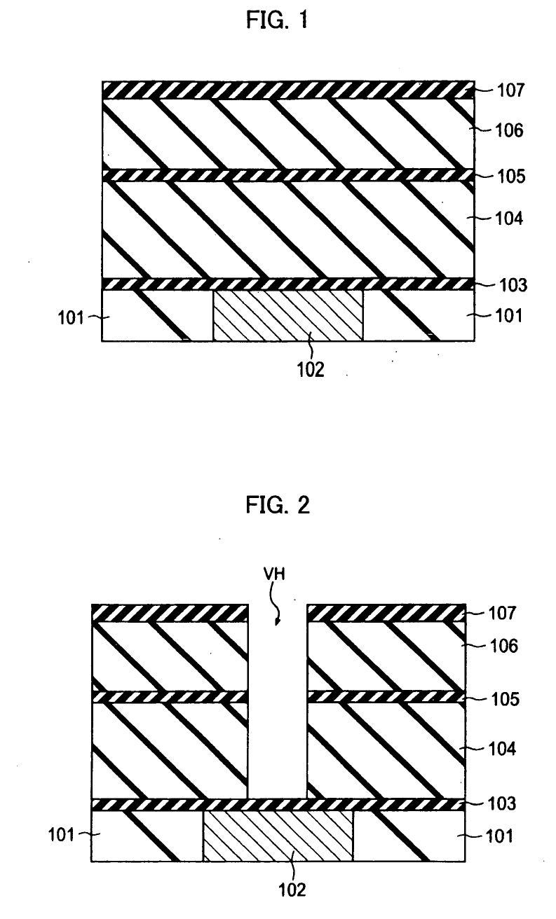

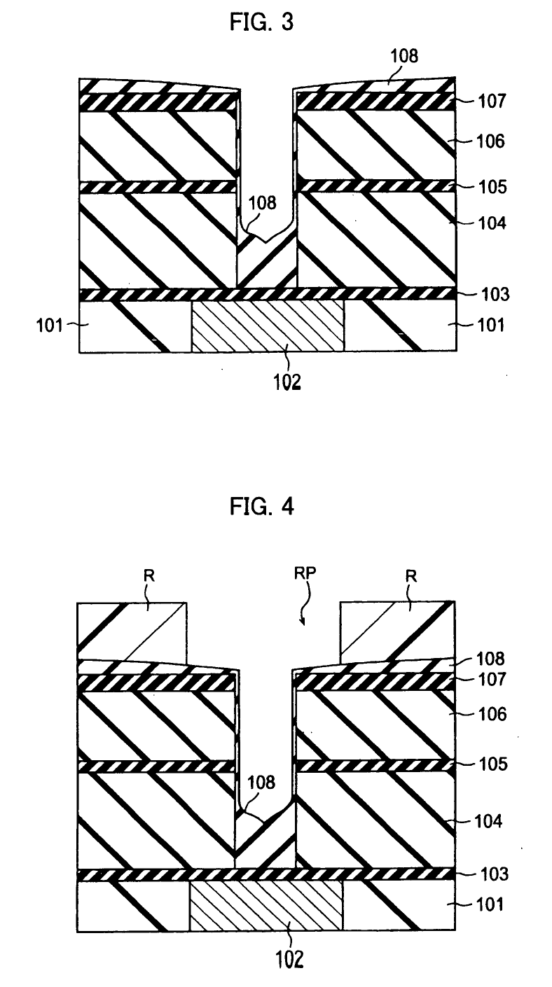

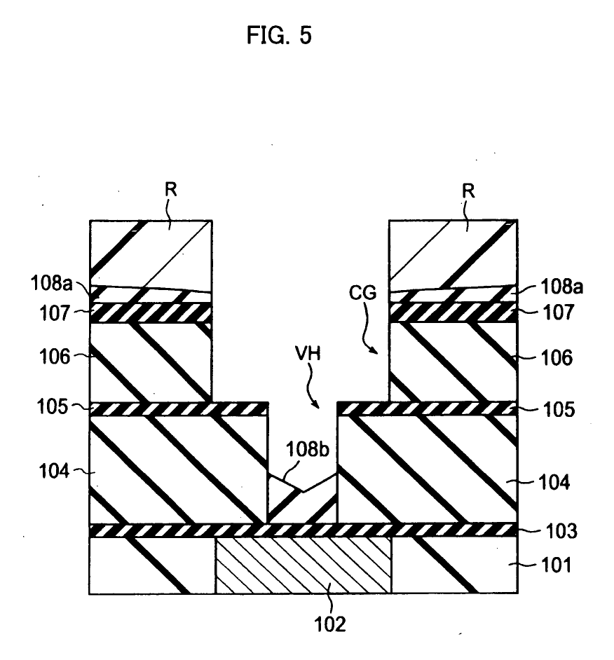

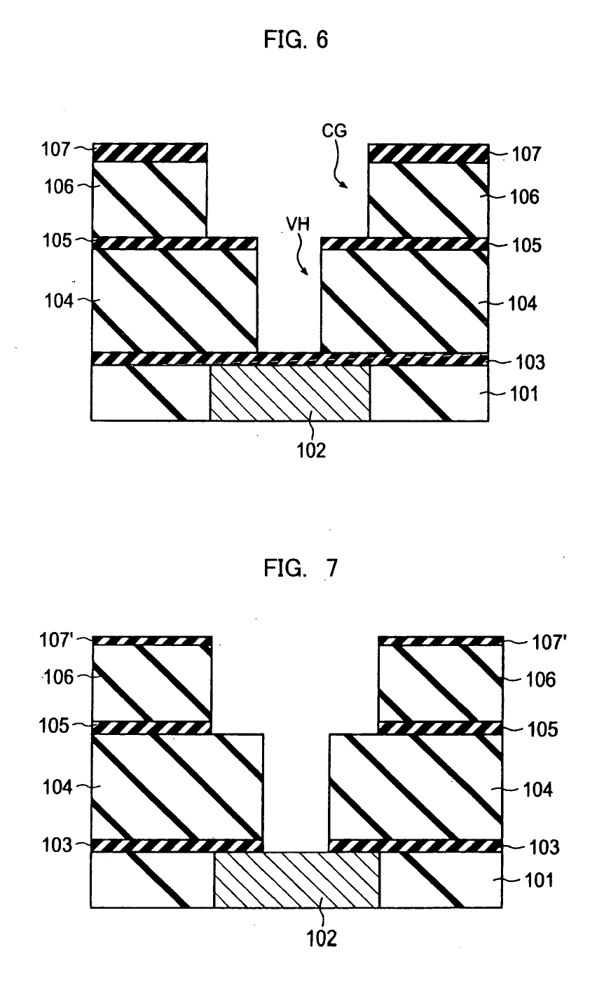

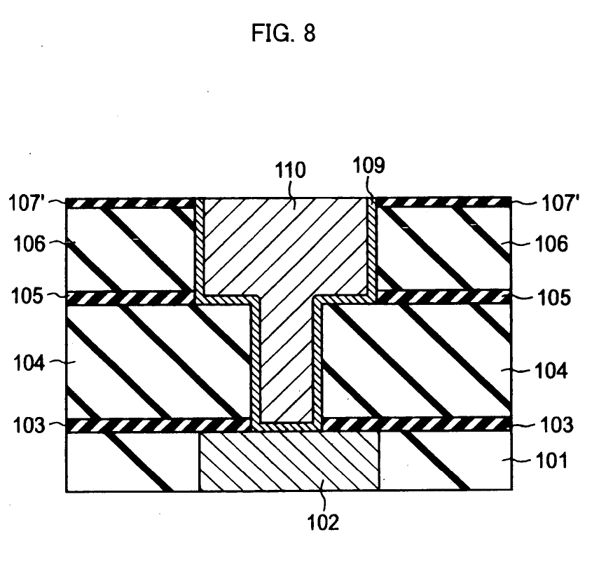

### BEST MODE FOR CARRYING OUT THE INVENTION

### FIRST EMBODIMENT

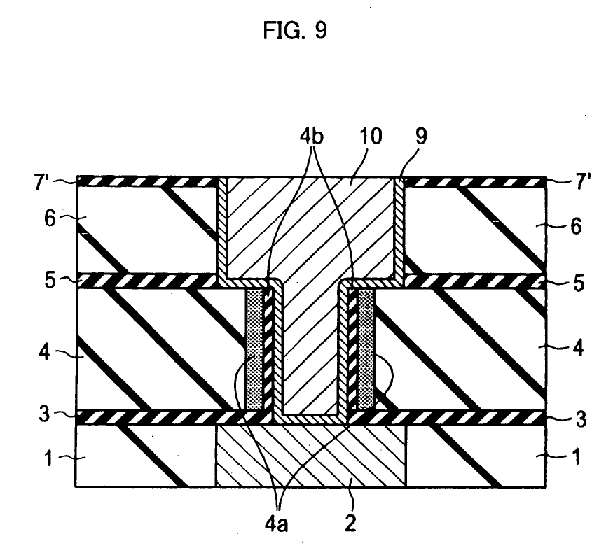

FIG. 9 is a sectional view of a wiring structure of a semiconductor device according to an embodiment of the present invention. Here, the case of further forming on a wiring layer a wiring pattern of a dual damascene structure wherein a via hole and a wiring layer are integrated will be explained as an example.

A conductive material is buried in a first interlayer insulation film 1 and a lower level wiring layer 2 is formed. On the first interlayer insulation film 1, an etching stopper film 3, a second interlayer insulation film 4, an etching stopper film 5, a third interlayer insulation film 6 and a hard mask film 7 are stacked in order.

A via hole is formed on the etching stopper film 3 and the second interlayer insulation film 4. The via hole has a pattern of an isolated approximately circular shape or a short trench shape when looking from the above, and is provided suitably on a required portion on the long lower level wiring layer 2.

A wiring trench having a little wider width than the via hole is formed on the etching stopper film 5 and the third interlayer insulation film 6. The wiring trench is formed to be a predetermined pattern of passing over the via hole.

A barrier metal layer 9 is formed on an inner wall of the wiring trench and the via hole, and copper 10 is buried in the wiring trench and the via hole over the barrier metal layer 9. As a result, a dual damascene structure is formed.

In the dual damascene structure of the present embodiment, particularly both of the second interlayer insulation film 4 and the third interlayer insulation film are composed of an organic based interlayer insulation material, preferably an organic based insulation material having lower relative permittivity than that of a normal inorganic interlayer insulation material, such as silicon dioxide.

Furthermore, as a characteristic point of the present embodiment, particularly, a silylated layer or a silylating agent diffusion layer 4a and a protective layer 4b composed of an inorganic based insulation material obtained by reacting a surface of the silylated layer are formed on a via hole side surface portion of the second interlayer insulation film 4 as a lower layer. As a material of the protective layer 4b, silicon oxide generated by reacting the silylated layer or the silylating agent diffusion layer 4a with oxygen may be mentioned as an example.

Note that according to a later explained example of a production method, a silylated layer or a silylating agent diffusion layer and a protective layer are also formed on a hole when forming a via hole formed on the third interlayer insulation film 6 in the same way as in the case of the inner walls, but they are removed when forming a wiring trench and does not appear on a completed dual damascene structure.

The reason of providing the protective layer 4b will be explained in a later explained production method.

Next, a method of forming the dual damascene structure will be explained with reference to the drawings.

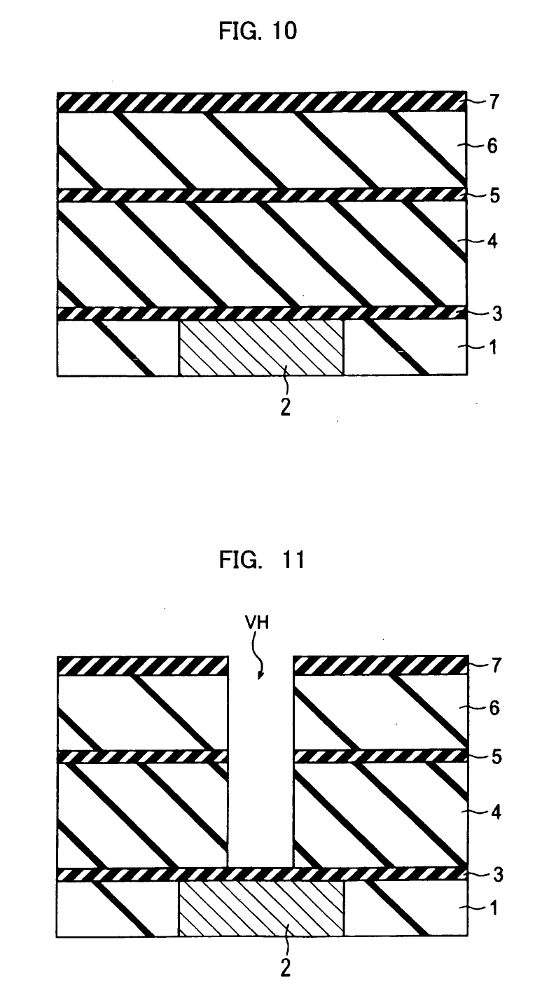

FIG. 10 to FIG. 18 are sectional views in producing a semiconductor device according to the present embodiment.

On a semiconductor substrate (not shown) formed with an element, a lower level wiring layer 2 buried in a first interlayer insulation film 1 in accordance with need is formed. The lower level wiring layer 2 may be formed by a dual damascene process to be explained below, but here, an embodiment of the present invention will be explained on a wiring layer formed thereon.

On the first interlayer insulation film 1, an etching stopper film 3, a second interlayer insulation film 4, an etching stopper film 5, a third interlayer insulation film 6 and a hard mask film 7 are formed in order by the CVD (Chemical Vapor Deposition) method or spin-coating method.

As the second and third interlayer insulation films 4 and 6, an organic based interlayer insulation film having low relative permittivity is preferable.

As an organic based interlayer insulation film having low relative permittivity, any one of a methyl group-containing SiO₂ film, a polyimide based polymer film, a parylene based polymer film, a Teflon (registered trademark) based polymer film, a polyarylether based polymer film and an amorphous carbon film doped with fluorine is used. Specifically, as methyl group-containing SiO₂, “LKD-T400 (product name)” made by the JSR Corporation may be used. As a polyarylether based polymer material, for example, “SiLK (trademark)” made by the Dow Chemical Company or “FLARE (trademark)” made by the Honeywell Electronic Materials may be used.

As a material for the etching stopper films 3 and 5 and the hard mask film 7, a material having high etching selectivity to an interlayer insulation film material is used. Also, particularly the hard mask film 7 has a role as a stopper of the CMP (Chemical Mechanical Polishing) of copper, and a material thereof is selected also by taking that point in consideration.

For example, when a polyarylether based resin is selected as an organic based low relative permittivity insulation material, silicon nitride is preferable as a material of the etching stopper films 3 and 5 and the hard mask film 7.

A specific example of forming the stacked films is, for example, as below.

First, a SiN film is formed to be 50 nm or so as an etching stopper film 3 by the CVD method. As the second interlayer insulation film 4, a polyarylether based resin having the relative permittivity of 2.6 is spin-coated, and a solvent is spun off by heating the substrate at 130° C. for 90 seconds to obtain the final film thickness of 350 nm. Also, the substrate is heated at 300° C. for one hour to cure the second interlayer insulation film 4. Next, as the etching stopper film 5, a SiN film is formed to be 50 nm or so by the CVD method. As the third interlayer insulation film 6, a polyarylether based resin having relative permittivity of 2.6 is spin-coated, and a solvent is spun off by heating the substrate at 130° C. for 90 seconds to obtain the final film thickness of 250 nm. Also, the substrate is heated at 300° C. for one hour to cure the third interlayer insulation film 6. Finally, as the hard mask film 7, a SiN film is formed to be 120 nm or so by the CVD method. In this example, since the hard mask film 7 and the etching stopper film 5 are the same material (SiN), a thickness of the hard mask film 7 is set to be a little thick so that a sufficient film thickness remains as a mask when forming a via hole or as a hard mask when performing the CMP of copper even when subtracting an etching stopper film thickness. When the thickness of the etching stopper 5 is 50 nm, 120 nm or so is sufficient for the hard mask film 7.

As shown in FIG. 11, a via hole VH is formed on the stacked films 3 to 7 by using a lithography technique and a dry etching technique.

A specific example of forming the via hole is, for example, as below.

An organic based anti-reflection film is formed on the hard mask film 7, and an acetal based chemically amplified resist is coated thereon. For example, by using a KrF excimer laser exposure apparatus, a via hole pattern is transferred to the resist and developed for patterning. When using KrF excimer laser exposure, for example, a hole having a diameter of 180 nm can be formed at minimum pitches of 360 nm.

After that, by reactive ion etching (RIE) using the resist pattern as a mask, the hard mask film 7, the third interlayer insulation film 6, the etching stopper film 5 and the second interlayer insulation film 4 are continuously etched by successively switching an etching gas. For example, a mixed gas of CHF₃, Ar and O₂ may be used when performing etching on the hard mask film 7, a mixed gas of NH₃ and H₂ may be used when performing etching on the third interlayer insulation film 6, a mixed gas of C₅F₈, CH₂F₂, Ar and O₂ may be used when performing etching on the etching stopper film 5, and a mixed gas of NH₃ and H₂ may be used when performing etching on the second interlayer insulation film 4. While depending on a resist material and a coating condition, when etching a fine hole having the above diameter and pitches, the resist and the organic based anti-reflection film are also etched off when performing etching on the third interlayer insulation film 6. In etching after the resist, etc. are etched off, the hard mask film 7 as the uppermost layer functions as an etching mask.

As a result, a via hole VH is formed.

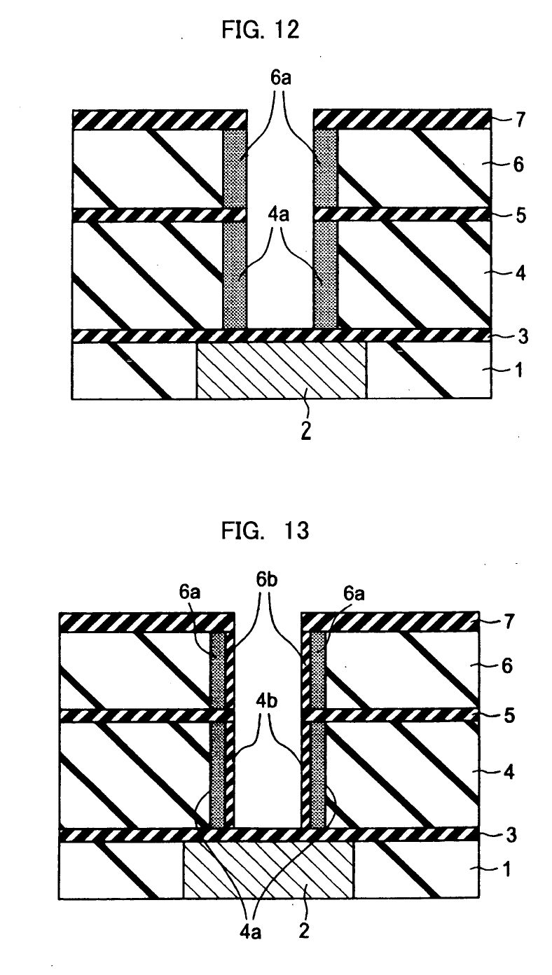

In a step shown in FIG. 12, a silylated layer or a silylated diffusion layer 4a is formed on an exposed surface of the second and third interlayer insulation films 4 and 6.

As a method of silylation, there are a vapor silylation resist process for exposing the substrate wherein the via hole VH is formed on the organic based interlayer insulation films 4 and 6 to vapor of a silylating agent and a method of doping the same in a solution including a silylating agent.

In the vapor silylation resist process, vapor of a silylating agent of hexamethyldisilazane (HMDS), dimethylsylildimethylamine (DMSDMA), trimethyldisilazane (TMDS), trimethyldimethylamine (TMSDMA), dimethylaminotrimethylsilane (TMSDEA), heptamethyldisilazane (HeptaMDS), aryltrimethylsilane (ATMS), hexamethyldisilane (HMD Silane), bis[dimethylamino]methylsilane (B[DMA]MS), bis[dimethylamino]dimethylsilane (B[DMA]DS), hexamethylcyclotrisilazane (HMCTS), or diaminosiloxane, etc. may be used.

Also, as a solution including a silylating agent, for example, a solution obtained by dissolving any one of the above silylating agents in a xylene, etc. and adding 2-methylpyrrolidone as a reaction catalyst may be used.

The organic based interlayer insulation films 4 and 6 are normally heated at a high temperature not to absorbing moisture and subjected to processing of removing an OH group as much as possible. However, due to a heat resistance problem, the heat processing cannot be performed at a very high temperature and an OH group is normally not completely removed. Also, since the inner walls after forming the via hole VH are exposed to a cleaning solution after etching or an air, an OH group is often bonded with an end of a polymer compound. In the above silylation process, the OH group and the silylating agent are brought to react and form a silylated layer on hole inner walls. Also, other than the OH group, the silylated layer is formed by reacting with non-bonded hands —O— of oxygen on the surface in some cases.

In this meaning, for promoting silylation, the organic based interlayer insulation films 4 and 6 may be heated at a lower temperature than the normal to be a degree of not deteriorating the performance, or heating only for a shorter time than the normal to increase a residual OH group.

Other than the silylated layer formed as above, a silylating agent diffusion layer obtained by diffusing a silylating agent from the silylation layer or a layer including both of a silylated polymer and a diffused silylating agent is generated in some cases. In this case, a layer indicated by the reference numbers 4a and 6a in FIG. 12 collectively indicates any one of the layers or a layer in a different state.

A specific example of silylation is, for example, as below.

In a silylation processing chamber, while placing the substrate on a hot plate and heating at 250°, it is exposed to vapor of a silylating agent, for example DMSDMA, of 75 Torr introduced into the chamber for 120 seconds. Under this condition, as shown in FIG. 12, mixed layers 4a and 6a of a silylated polymer and diffused silylating agent, respectively having a thickness of about 30 nm, are formed on the hole exposed inner walls of the organic based second and third interlayer insulation films 4 and 6.

In the method of exposing the substrate to vapor of a silylating agent as above, the same chamber as those used in the HMDS processing for improving adhesiveness before applying the resist may be used. Accordingly, silylation can be easily realized by the apparatus configuration of a conventional coater developer, etc. as it is, or by using what obtained by adding a unit to a part thereof.

Also, in the method of doping the substrate in a silylated solution, a generally used batch or single wafer chemical processing apparatus may be used. Accordingly, silylation can be easily realized by diverting a conventional apparatus.

In a step shown in FIG. 13, surface portions of the silylated layer or silylating agent diffused layers 4a and 6a are turned into, for example, silicon oxide to form protective layers 4b and 6b. When the protective layers 4b and 6b are composed of silicon oxide, it is sufficient only if the substrate is exposed to oxide plasma, and a normally used dry ashing apparatus and dry etching apparatus can be used. When exposing the substrate to oxide plasma, it is preferable to perform processing by setting oxide plasma energy low to a certain degree so as not to sputter surfaces of the silylated layer or silylating agent diffusion layers 4a and 6a.

A specific example of forming the protective layer is, for example, as below.

By using a Transfer Coupled plasma etching apparatus as a dry etching apparatus, oxygen plasma processing is performed on the substrate. A condition at this time is, for example, to expose the substrate brought to be −10° C. for 20 seconds to oxygen plasma generated under an O₂ gas flow amount of 30 sccm, a pressure of 5 mTorr, the upper RF power of 20 W and the lower RF power of 5 W. As a result, silylated molecules or a silylating agent reacts with oxygen, and silicon oxide layers 4b and 6b are formed to be a thickness of about 8 nm on the hole inner wall surfaces of the second and third interlayer insulation films 4 and 6 as shown in FIG. 13.

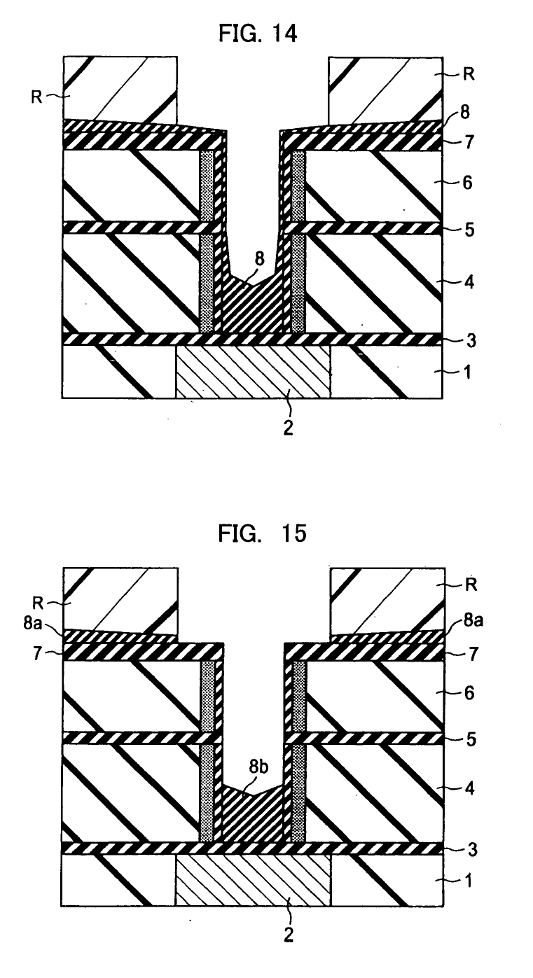

In a step shown in FIG. 14, an organic film 8 is formed for etching protection of a via hole bottom portion first.

As an organic film 8, an organic based anti-reflection film can be used. In this case, it is sufficient if a burying height on the via hole bottom portion at the time of spin-coating the organic based anti-reflection film 8 is lower than a height of the etching stopper film 5 in the middle, and side walls of the via hole at the upper portion are preferably thinly covered with the organic based anti-reflection film 8.

Continuously, a resist pattern R for a wiring trench is formed.

A specific example of forming a resist is, for example, as below.

A chemically amplified negative resist R is coated to be a thickness of 530 nm or so on the organic based anti-reflection film 8, and a wiring trench pattern is transferred by a KrF excimer laser exposure apparatus and developed. As a result, a resist R of a wiring trench pattern having the same width as or a little wider than a via hole diameter is formed on an upper portion of the hard mask film 7. Here, a minimum width of the wiring trench pattern is 180 nm, which is the same as the via hole diameter, and the minimum pitches are 360 nm.

When being out of the line width standard and alignment standard in a lithography step of a wiring trench, the organic based anti-reflection film 8 and the resist R are peeled off and an organic based anti-reflection film and the resist are coated again. When peeling off the organic based anti-reflection film 8 and the resist R, it is cleaned up with a cleaning solution after oxygen plasma ashing.

In the oxygen plasma ashing, for example, a down flow asher is used, O₂ (a flow amount: 1700 sccm) and a mixed gas (a flow amount: 400 sccm) of H₂ and N₂ as a buffer gas are flown into a chamber under a gas pressure of 1.5 Torr to perform processing with RF power of 1700 W at a substrate temperature of 200° C. for 90 seconds. At this time, end surfaces in the hole of the second and third interlayer insulation films 4 and 6 are protected by the protective layers 4b and 6b.

Generally used RCA cleaning method is used in cleaning process after that and, for example, an SC-1 cleaning solution (a mixed solution of NH₄OH, H₂O₂ and H₂O) and an SC-2 cleaning solution (a mixed solution of HCl, H₂O₂ and H₂O) are used.

In a step shown in FIG. 15, etching is performed on the organic based anti-reflection film 8 by using the formed resist R as a mask. At this time, an organic based anti-reflection film portion being thinly coated from the middle to upper portion of the inner walls of the via holes VH is removed, and the organic based anti-reflection film 8 is divided to a portion 8a immediately below the resist R and a portion 8b at the via hole bottom portion.

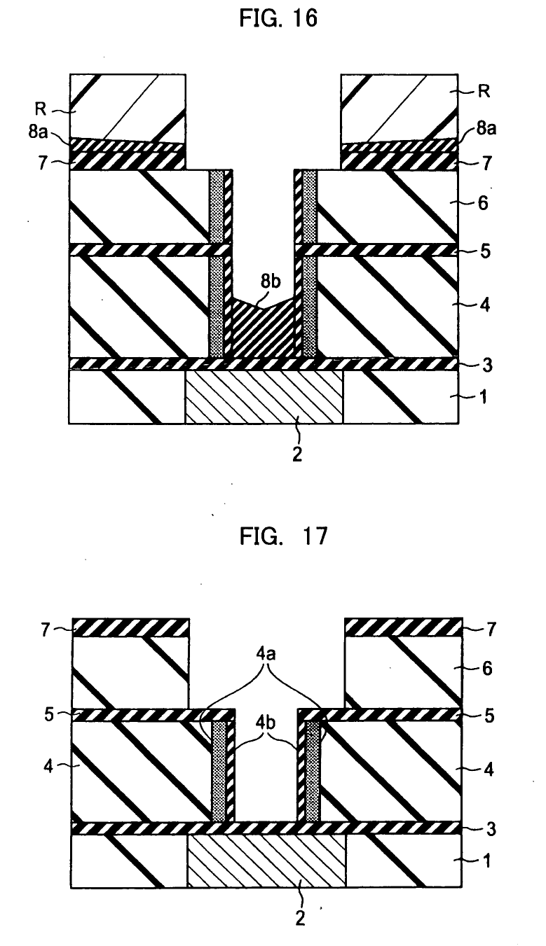

In a subsequent step shown in FIG. 16, dray etching by using the resist R is performed to remove a portion of the hard mask film 7 exposed to the wiring trench pattern. When the hard mask film 7 is silicon nitride, a mixed gas of CHF₃, Ar and O₂ is used in the dry etching.

In this state, dry etching for forming a wiring trench is performed by switching an etching gas.

A specific example of the etching is, for example, as below.

First, etching by using a mixed gas of C₅F₈, Ar and O₂ is performed to etch the protective layer (silicon oxide film) 6b on the hole inner wall portion of the third interlayer insulation film 6 and a mixed layer 6a of silylated polymer and a diffused silylating agent. Continuously, by switching to an etching gas of an organic based insulation material, etching by using the resist R as a mask is performed to transfer the wiring trench pattern to the third interlayer insulation film 6. The resist R and the organic based anti-reflection film 8a are composed of the same organic based material as the third interlayer insulation film 6, so that, while depending on a film thickness of the resist and a depth of the wiring trench, these films R and 8a are normally removed when performing etching on the third interlayer insulation film 6. After removing the resist R, the etching stopper film 5 in the middle functions as a protective layer of the via hole VH. A section after the etching is shown in FIG. 17.

Note that when the resist R is not etched off when performing etching on the third interlayer insulation film 6 or in the case where controllability of an etching end point is so high that a shape of the via hole VH does not deform during the etching or the previous etching of the protective layer 6b, etc., the etching stopper 5 in the middle is unnecessary and a formation step thereof can be omitted in the step in FIG. 10. Also, when the organic based anti-reflection film portion 8b at the via hole bottom portion remains even a little at the etching end point shown in FIG. 17, the lowermost layer etching stopper film 3 can be also omitted. Inversely, when the lowermost etching stopper film 3 is sufficiently thick, a step of burying an organic substance of an anti-reflection film, etc. can be omitted.

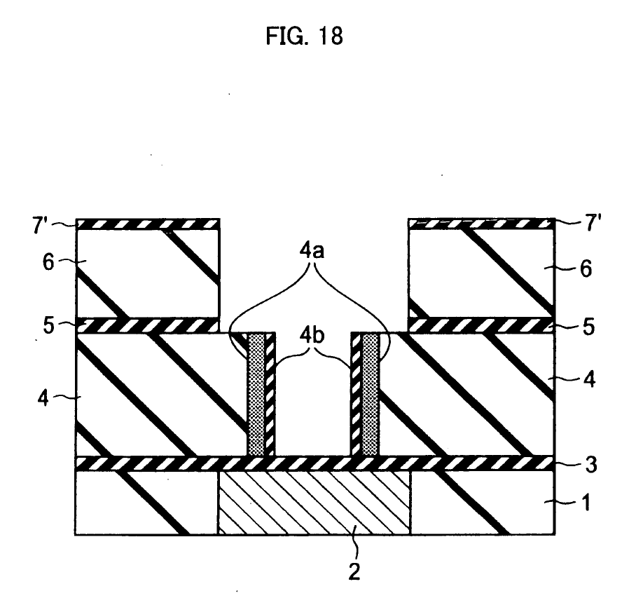

In the illustrated example having the etching stopper films 3 and 5, a step shown in FIG. 18 is necessary. Namely, an etching stopper film 3 portion at the via hole bottom surface and an etching stopper film 5 portion on the wiring trench bottom surface are removed by overall etching.

A specific example of the overall etching is, for example, as below.

When the etching stopper films 3 and 5 are composed of silicon nitride, overall etching (etch back) by using a mixed gas of C₅F₈, CH₂F₂, Ar and O₂ is performed to remove the etching stopper films 3 and 5 in the via hole or in the wiring trench. At this time, a thickness of the hard mask film 7 composed of the same material reduces and it becomes a thinner film 7′ than the initial film.

Then, after cleaning the substrate, a barrier metal layer and a copper plating seed film are formed on inner walls of the via hole and wiring trench, and copper is buried in the via hole and wiring trench at a time by using a plating technique. Then, by using the CMP technique, excessive copper on the upper surface is removed. At this time, the hard mask film 7′ functions as an end point stopper of the CPM. After that, by removing the hard mask film 7′, the dual damascene copper wiring structure shown in FIG. 9 is completed.

Note that in the case where controllability of the CPM end point of copper is high even without the hard mask film 7′ and the resist is not etched off when performing etching of the via hole shown in FIG. 11 and performing etching of the wiring trench shown in FIG. 17, the hard mask film 7′ can be omitted from the beginning.

In the present embodiment, since the via hole inner wall portions of the second and third interlayer insulation films 4 and 6 are silylated to form the protective layers 4b and 6b, even in the case where the second and third interlayer insulation films 4 and 6 are composed of an organic based insulation material having low relative permittivity, the via hole inner walls are not attacked in a step of peeling a resist or other organic based material and etching other organic based insulation material. Thus, there is an advantage that a preferable hole shape can be maintained till the end. Therefore, the barrier metal layer 9 can be preferably formed, the copper 10 does not diffuse in the interlayer insulation films 4 and 6 when burying the copper 10, and a void of the copper 10 does not arise on the via hole portion. Furthermore, between wirings or a mutual distance between the wiring and the via hole portion is kept to be constant. As a result, electric characteristics of a semiconductor device using the multilayer wiring structure are preferable.

Since the silylation step only exposes the substrate to vapor or a solution of a silylating agent, a conventional processing apparatus can be used as it is or by partially changed, so that it does not cause a big increase of costs in the process.

By combining the dual damascene copper wiring structure and an organic based interlayer insulation film having low relative permittivity, a highly integrated semiconductor device operating at a high speed with low power consumption can be easily produced at low coasts.

### SECOND EMBODIMENT

As a modified example of a first embodiment, the second interlayer insulation film 4 formed with a via hole can be composed of an inorganic based insulation material.

In the step shown in FIG. 10, instead of the second interlayer insulation film 4 composed of an organic based insulation material, a second interlayer insulation film composed of an inorganic based insulation material, for example, silicon oxide is formed. The inorganic based second interlayer insulation film will be referred to by the reference number 40 in the explanation below and in drawings.

A via hole VH is formed by switching from an organic based etching condition to an inorganic based etching condition in the same way as in FIG. 11, and silylation of the organic based interlayer insulation film and formation of a protective layer are performed in subsequent steps shown in FIG. 12 and FIG. 13.

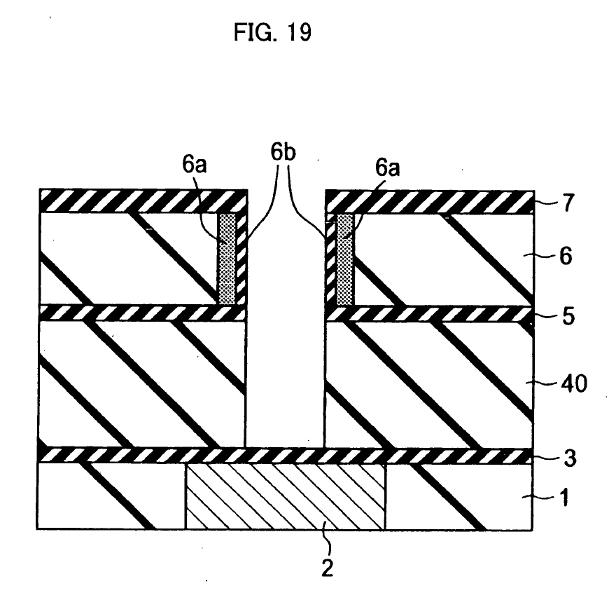

FIG. 19 is a sectional view after the formation of a protective layer in the second embodiment.

Since the second interlayer insulation film 40 is inorganic based, it is not silylated, so that a protective layer is not formed, either. Since a material of the second interlayer insulation film 40 itself is an inorganic based material, which is scarcely corroded when performing etching on an organic based material, formation of a protective film is not necessary. On the other hand, on the via hole inner walls of the organic based third interlayer insulation film 6 are formed with a silylated layer or a silylated agent diffusion layer 6a and a protective layer 6b in the same way as in the first embodiment.

Below, in the same way as in the first embodiment, a step of burying the via hole of an organic material (for example, an organic based anti-reflection film) and a step of forming a wiring trench are performed, and copper is buried in the via hole and wiring trench at a time to complete the copper wiring structure.

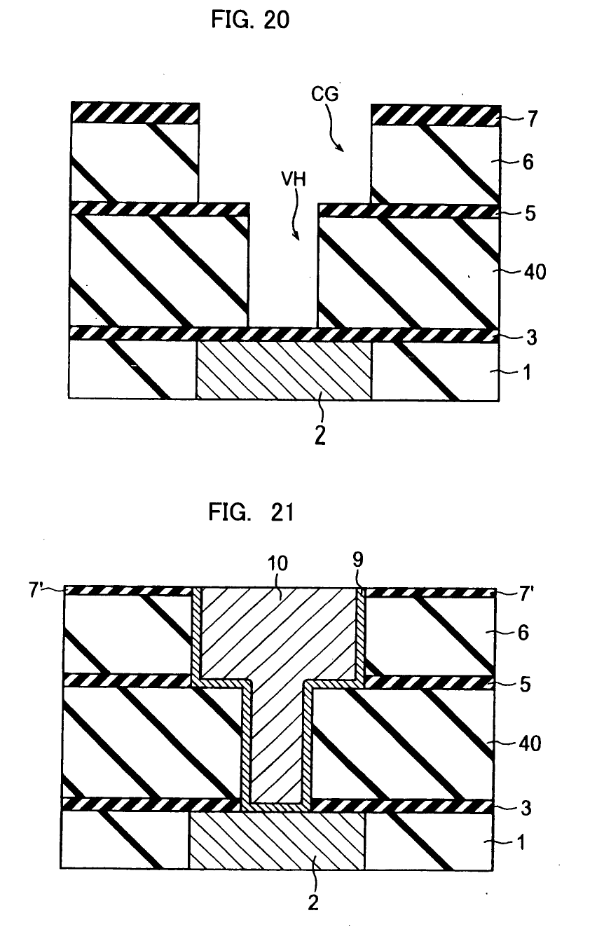

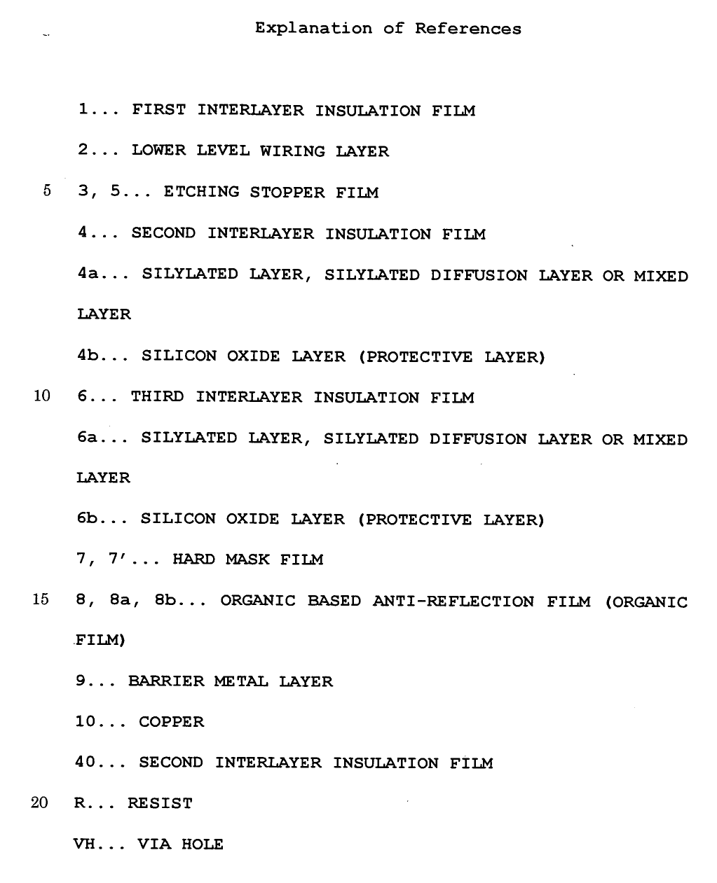

FIG. 20 is a sectional view after forming the wiring trench. FIG. 21 is a sectional view of the completed copper wiring structure.

In the second embodiment, the silylated layer or silylating agent diffusion layer 6a and the protective layer 6b are formed only on the side of the third interlayer insulation film 6 as an upper layer, but they are removed when performing etching on the wiring trench (FIG. 20) and do not appear on the completed wiring structure (FIG. 21).

However, since the hole sidewalls on the side of the third interlayer insulation film 6 as an upper layer are protected partway in the present embodiment, there is an advantage that a shape of a hole upper portion does not deform even if formation of a resist at the time of photolithography of a wiring trench is repeated for any number of times. Particularly, in the case of applying a borderless contact structure wherein a wiring trench pattern width and a via hole diameter below that are almost equal, when a shape of a hole upper portion is deformed by resist peeling, etc., it directly leads to wiring pattern deformation. But in the present embodiment, since the hole inner walls of the third interlayer insulation film 6 is protected by the protective layer 6b until a required point, a problem of pattern deformation as such can be effectively prevented.

Particularly, prevention of pattern deformation on a via hole portion is effective for controlling variations between final wirings or a mutual distance between the wiring and via hole, and a void at burying copper becomes a problem on a via hole portion with a small diameter. Therefore, the same effects as in the first embodiment can be obtained only by protecting the via hole inner walls of the interlayer insulation film 4 as a lower layer as in the present embodiment.

On the other hand, as to a reduction of a capacity between wirings, the third interlayer insulation film 6 is composed of an organic based insulation material having low relative permittivity in the present embodiment, there are advantages that at least a coupling capacitance between wirings can be reduced, and a semiconductor device at a high speed with low power consumption comparing with the case of using only an inorganic interlayer insulation film can be preferably produced.

### THIRD EMBODIMENT

In the above first and second embodiments, when the organic based interlayer insulation films are composed of a porous film, diffusion of a silylating agent is accelerated and a silylated layer or a silylating agent diffusion layer can be easily formed.

A specific example of forming the porous film is as below.

As the third interlayer insulation film 6 (and second interlayer insulation film 4) shown in FIG. 10, a porous type polyarylether based resin is used. Since there are a number of vacancies, a silylating agent easily diffuses in the silylation step shown in FIG. 12, and a more stable silylating agent diffusion layer, silylated layer and silicon oxide film (protective layer) are formed on the hole inner walls.

An interlayer insulation film of a porous type polyarylether based resin is obtained by performing spin-coating of a liquid material obtained by dissolving a polyarylether based polymer and organic oligomer in a solvent on a substrate, spinning off the solvent by heating the substrate at 130° C. for 90 seconds, then heating the substrate at 300° C. for one hour or so for curing. When heating for curing, the organic oligomer is pyrolyzed and a great number of fine vacancies are formed.

In the subsequent silylation processing, while placing the substrate on a hot plate in the chamber and heating at 250° C., the substrate is exposed to vapor of a silylating agent DMSDMA flown into the chamber by a flow amount of 50 Torr for exactly 90 seconds. As a result, a mixed layer of silylated molecules and a diffused silylating agent is formed to be thicker than that in the first embodiment, for example about 30 nm, on a hole inner wall portion of an organic based interlayer insulation film.

After that, in the same way as in the first embodiment, a protective layer composed of silicon oxide is formed by oxide plasma processing.

### FOURTH EMBODIMENT

In the first and second embodiments explained above, those added with a silylating agent entirely in the organic based interlayer insulation film at first can be used. Doe to this, the silylation step shown in FIG. 12 becomes unnecessary.

A specific example of forming the organic based interlayer insulation film containing a silylating agent is as below.

When forming the third interlayer insulation film 6 (and the second interlayer insulation film 4) shown in FIG. 10, a liquid material obtained by dissolving polyarylether based polymer and DMSDMA as a silylating agent by 10 wt % or so in a solvent is spin-coated on a surface to be stacked with an organic insulation film, the substrate is heated at 130° C. for 90 seconds to spin off the solvent, then, the substrate is heated at 300° C. for one hour for curing. As a result, an organic based interlayer insulation film containing a silylating agent is easily formed. A content of the silylating agent is determined, so that relative permittivity of the organic based insulation material does not become very high.

The organic based interlayer insulation film contains a silylating agent or is partially silylated, so that silylation processing can be omitted. After that, in the same way as in the first embodiment, only by exposing the substrate to oxygen plasma, a protective layer composed of silicon oxide can be easily formed on the hole inner walls.

In the above first to fourth embodiments, the case of forming a dual damascene structure wiring layer on a wiring layer is explained with drawings, but they can be applied to the case of forming the dual damascene structure wiring layer on the substrate in the same way.

Also, the etching stopper films 3 and 5 and the hard mask films 7 and 7′ can be omitted depending on the case as explained above. Note that the etching stopper film 5 in the middle is preferably provided as far as possible in terms of easy controllability of dry etching.

Furthermore, an organic material to be buried on the via hole bottom surface is not limited to an anti-reflection film material. For example, in the case of applying a multilayer resist process using a lower layer film and a Si containing resist, or the lower layer film, an SOG (Spin On Glass) and an upper layer resist, in the photolithography step in forming a wiring trench, the lower layer film may be left on the via hole bottom portion. Namely, when performing dry etching on the lower layer film, a part of the lower film may be left on the hole bottom portion and used as a dry etching stopper.

Also, in the above four embodiments, a protective layer composed of silicon oxide was formed by exposing to oxygen plasma in the silylation step, but it is just an example and a protective layer composed of, for example, silicon nitride may be formed by exposing to nitride plasma or nitride radical.

Other than the above, a variety of modifications may be made within the scope of the present invention.

1. A method of producing a semiconductor device, including:
a step of depositing organic based interlayer insulation films (4, 6);
a step of forming an opening portion on the organic based interlayer insulation films (4, 6); and
a step of performing silylation to reform a wall surface portion of the organic based interlayer insulation films (4, 6) exposed in said opening portion.

2. A method of producing a semiconductor device according to claim 1, characterized by further including a step of forming protective layers (4b, 6b) including an inorganic based insulation material on a surface of said opening portion wall surface subjected to silylation.

3. A method of producing a semiconductor device according to claim 2, characterized that the inner wall surface of said opening portion including silylated molecules as a result of silylation is exposed to oxide plasma to form a silicon oxide film for protecting the inner wall of the opening portion in a step of forming said protective films (4b, 6b).

4. A method of producing a semiconductor device according to claim 1, characterized by further including a step of forming an organic based substance in a state of being formed with said opening portion and removing the organic based substance at least from said opening portion after said silylation.

5. A method of producing a semiconductor device according to claim 4, characterized that
said opening portion comprises a via hole (VH) formed by penetrating two interlayer insulation films (4, 6) in a dual damascene wiring process; and
a step of forming a wiring trench (CG) connected to said via hole (VH) on an upper interlayer insulation film (6) of said two interlayer insulation films (4, 6) through the steps of coating a photo resist (R) and performing exposure and development in a state of being formed with the via hole (VH) is further included.

6. A method of producing a semiconductor device according to claim 5, characterized by further including a step of forming an etching stopper film (5) for protecting a via hole (VH) on a lower interlayer insulation film (4) of said two interlayer insulation films (4, 6) in advance between said two interlayer insulation films (4, 6) when etching for forming said wiring trench (CG).

7. A method of producing a semiconductor device according to claim 6, characterized that said etching stopper film (5) comprises a silicon nitride film.

8. A method of producing a semiconductor device according to claim 5, characterized that at least said upper layer interlayer insulation film (6) formed with said wiring trench (CG) of said two interlayer insulation films (4, 6) include an organic based insulation material.

9. A method of producing a semiconductor device according to claim 8, characterized that said organic based insulation material is any one of a methyl group-containing SiO₂ film, a polyimide based polymer film, a parylene based polymer film, a Teflon (registered trademark) based polymer film, a poly aryl ether based polymer film and an amorphous carbon film doped with fluorine.

10. A method of producing a semiconductor device according to claim 1, characterized by forming a porous organic insulation film as said organic based interlayer insulation films (4, 6).

11. A method of producing a semiconductor device including a step of forming an opening portion on organic based interlayer insulation films (4, 6), including:
a step of depositing organic based interlayer insulation films (4, 6) containing a silylating agent;
a step of forming an opening portion on the organic based interlayer insulation films (4, 6); and
a step of forming protective layers (4b, 6b) comprise an inorganic based interlayer insulation material on an inner wall surface of said opening portion containing a silylating agent.

12. A method of producing a semiconductor device according to claim 11, characterized that said protective film comprises silicon oxide.

13. A method of producing a semiconductor device according to claim 11, characterized that an silicon oxide film for protecting an inner wall surface of the opening portion is formed by exposing the inner wall surface of said opening portion containing a silylating agent to oxygen plasma in a step of forming said protective films (4b, 6b).

14. A semiconductor device, comprising two organic based interlayer insulation films (4, 6) stacked on top of another, wherein a via hole (VH) is formed on a lower layer interlayer insulation film (4) and a wiring trench (CG) connected to said via hole (VH) is formed on an upper layer interlayer insulation film (6) of the two organic based interlayer insulation films (4, 6), and having a wiring configuration that a conductive material (9, 10) is buried in the wiring trench (CG) and said via hole (VH); wherein
an inner wall portion of said via hole (VH) of a lower layer interlayer insulation film (4) of said two interlayer insulation films (4, 6) is provided with a silylated molecules containing layer (4a) and a protective layer (4b) includes an inorganic based insulation substance formed on a via hole (VH) inner wall surface portion of the silylated molecules containing layer (4a).

15. A semiconductor device according to claim 14, characterized that said protective layer (4b) comprises silicon oxide.

16. A semiconductor device according to claim 14, characterized that said opening portion comprises a via hole (VH) formed by penetrating two interlayer insulation films (4, 6) in a dual damascene wiring process.

17. A semiconductor device according to claim 14, characterized that an etching stopper film (5) for protecting a via hole (VH) of a lower layer interlayer insulation film (4) of said two interlayer insulation films (4, 6) is formed between said two interlayer insulation films (4, 6).

18. A semiconductor device according to claim 14, characterized that said etching stopper film (5) comprises a silicon nitride film.

19. A semiconductor device according to claim 14, characterized that an organic based insulation material composing said two interlayer insulation films (4, 6) is any one of a methyl group-containing SiO₂ film, a polyimide based polymer film, a parylene based polymer film, a Teflon (registered trademark) based polymer film, a poly aryl ether based polymer film and an amorphous carbon film doped with fluorine.

20. A semiconductor device according to claim 14, characterized that said two organic based interlayer insulation films (4, 6) comprise a porous organic insulation film.
